(19) United States
(12) Patent Application Publication
(10) Pub. No.: US 2011/0180815 A1
(43) Pub. Date: Jul. 28, 2011

(54) OPTICAL DEVICE, OPTICAL TRANSMISSION DEVICE, AND METHOD OF MANUFACTURING OPTICAL DEVICE

(75) Inventor: Tetsuya MIYATAKE, Kawasaki (JP)

(73) Assignee: FUJITSU LIMITED, Kawasaki-shi (JP)

(21) Appl. No.: 13/013,641

(22) Filed: Jan. 25, 2011

(30) Foreign Application Priority Data
Jan. 26, 2010 (JP) 2010-14780

(51) Int. Cl. H01L 31/12; H01L 31/18

(52) U.S. Cl. 257/84; 438/24; 257/E33.077; 257/E21.328

(57) ABSTRACT

An optical transmission board includes a base having light transmissibility, and an amorphized part provided in a lens-like shape in the base, the lens-like shape part having a different refractive index from the rest of the base.

### CROSS-REFERENCE TO RELATED APPLICATIONS

This application is based upon and claims the benefit of priority of the prior Japanese Patent Application No. 2010-14780, filed on Jan. 26, 2010, the entire contents of which are incorporated herein by reference.

### FIELD

The present embodiments relate to an optical device, an optical transmission device including the same, and a method of manufacturing an optical device.

### BACKGROUND

An optical transmission board has already been disclosed in which first- and second-refractive-index members having different refractive indices are provided in a through hole of a base substrate and a condensing lens is attached at the exit of the through hole.

In the optical transmission board, the first- and second-refractive-index members, having different refractive indices from the base substrate, and the condensing lens are provided to the base substrate. Since members having different refractive indices from the base substrate are employed, such members may come off the base substrate.

### SUMMARY

According to an aspect of the disclosed embodiments, an optical device includes a base having light transmissibility, and an amorphized part provided in a lens-like shape in the base by, the lens-like shape part having a different refractive index from the rest of the base.

The object and advantages of the disclosed embodiments will be realized and attained by at least the features, elements and combinations particularly pointed out in the claims.

It is to be understood that both the foregoing general description and the following detailed description are exemplary and explanatory and are not restrictive of the disclosed embodiments, as claimed.

### BRIEF DESCRIPTION OF DRAWINGS

FIG. 1 illustrates a state where an optical transmission device according to a first embodiment is on a printed circuit board;

FIG. 2 is an enlarged view of a part of the optical transmission device according to the first embodiment;

FIGS. 3A and 3B illustrate a method of forming a refractive-index-changing portion in an optical transmission board;

FIG. 4 illustrates an optical transmission device according to a second embodiment;

FIGS. 5A and 5B illustrate a method of forming a refractive-index-changing portion in the optical transmission board according to the second embodiment;

FIGS. 6A and 6B illustrate the method of forming the refractive-index-changing portion in the optical transmission board according to the second embodiment;

FIGS. 7A and 7B illustrate a variation of the method of forming the refractive-index-changing portion in the optical transmission board according to the second embodiment;

FIG. 8 illustrates an optical transmission device according to a third embodiment; and

FIG. 9 illustrates an optical transmission device according to a fourth embodiment.

### DESCRIPTION OF EMBODIMENTS

Embodiments will now be described with reference to the drawings.

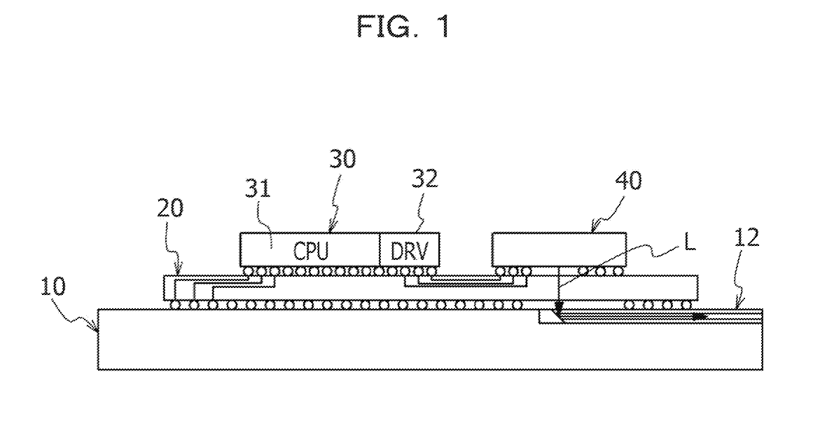

FIG. 1 illustrates a state where an optical transmission device according to a first embodiment is on a printed circuit board. As illustrated in FIG. 1, a printed circuit board 10 is mounted with an optical transmission device according to the first embodiment. The optical transmission device includes an optical transmission board 20, and an electronic component 30 and an optical semiconductor device 40 both mounted on the optical transmission board 20. The printed circuit board 10, the optical transmission board 20, the electronic component 30, and the optical semiconductor device 40 are used for electronic apparatuses such as servers and super computers.

The printed circuit board 10 functions as, but is not limited to function as, a mother board of an electronic apparatus, for example. The optical transmission board 20 functions as an interposer. The optical transmission board 20 is made of silicon.

The electronic component 30 includes a central processing unit (CPU) 31 and a driver 32. The CPU 31 receives an electrical signal from the printed circuit board 10. In accordance with the electrical signal received by the CPU 31, the driver 32 outputs a drive signal to the optical semiconductor device 40. The optical semiconductor device 40 emits a laser beam toward the printed circuit board 10 in accordance with the drive signal input thereto. The optical semiconductor device 40 is an emitting device, specifically, a vertical-cavity surface-emitting laser (VCSEL), and is a surface-receiving photodiode (PD).

The printed circuit board 10 and the electronic component 30 are connected to each other with wires and through the optical transmission board 20. The electronic component 30 and the optical semiconductor device 40 are connected to each other with wires and on the optical transmission board 20.

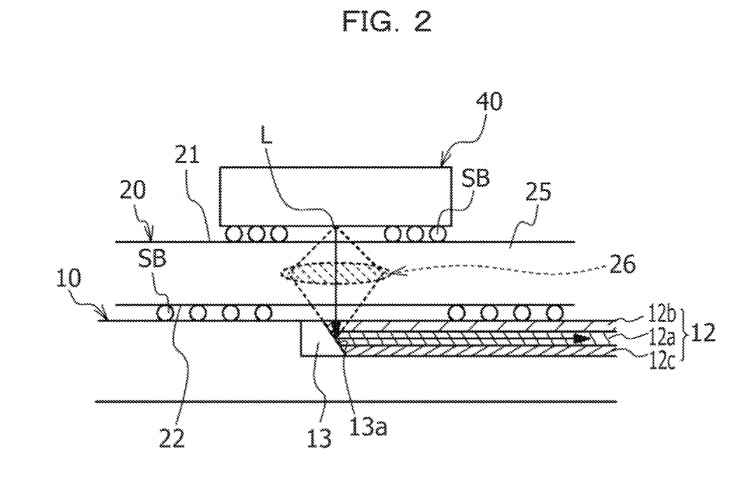

FIG. 2 is an enlarged view of a part of the optical transmission device according to the first embodiment. The printed circuit board 10 is provided thereinside with an optical waveguide 12 and an lens-like shape part 13. The optical waveguide 12 includes a core portion 12a and clad portions 12b and 12c provided around the core portion 12a. The core portion 12a has a larger refractive index than the clad portions 12b and 12c. The lens-like shape part 13 includes a reflector 13a. The reflector 13a is angled with respect to the optical axis of the optical semiconductor device 40. The optical waveguide 12 may be provided on a surface of the printed circuit board 10. A laser beam L emitted from the optical semiconductor device 40 is transmitted through the optical transmission board 20 in the thickness direction of the optical transmission board 20, is reflected substantially perpendicularly by the reflector 13a, and travels through the core portion 12a of the optical waveguide 12.

The optical transmission board 20 is made of silicon. The optical transmission board 20 has thereinside a refractive-index-changing portion 26 between a top surface 21 and a bottom surface 22. The refractive-index-changing portion 26 has a convex-lens-like shape. The refractive-index-changing portion 26 is formed by partially altering the properties of a base substrate 25 by amorphization or the like. The refractive-index-changing portion 26 has a larger refractive index than the rest of the base substrate 25. The refractive-index-changing portion 26 is amorphous. The base substrate 25 is crystalline. The optical transmission board 20 is mounted on the printed circuit board 10 with solder bumps SB.

The laser beam L emitted from the optical semiconductor device 40 travels into the base substrate 25 while diverging radially, and enters the refractive-index-changing portion 26. The laser beam L that has entered the refractive-index-changing portion 26 travels through the refractive-index-changing portion 26 while converging at a specific angle. The laser beam L traveling inside the refractive-index-changing portion 26 is refracted at an angle corresponding to the relative refractive-index difference between the base substrate 25 and the refractive-index-changing portion 26 and the curvature of the refractive-index-changing portion 26, and is emitted from the refractive-index-changing portion 26. The laser beam L emitted from the refractive-index-changing portion 26 further travels through the base substrate 25 while converging toward the reflector 13a. Thus, the loss of the laser beam L is reduced, and the laser beam L is efficiently guided to the optical waveguide 12. The optical semiconductor device 40 is mounted on the optical transmission board 20 with solder bumps SB. The wavelength of the laser beam L emitted by the optical semiconductor device 40 is set so as to exceed a value corresponding to the band gap of the optical transmission board 20. Specifically, the wavelength of the laser beam L is set to 1.1 μm or longer. Thus, the laser beam L is transmitted through the optical transmission board 20 made of silicon.

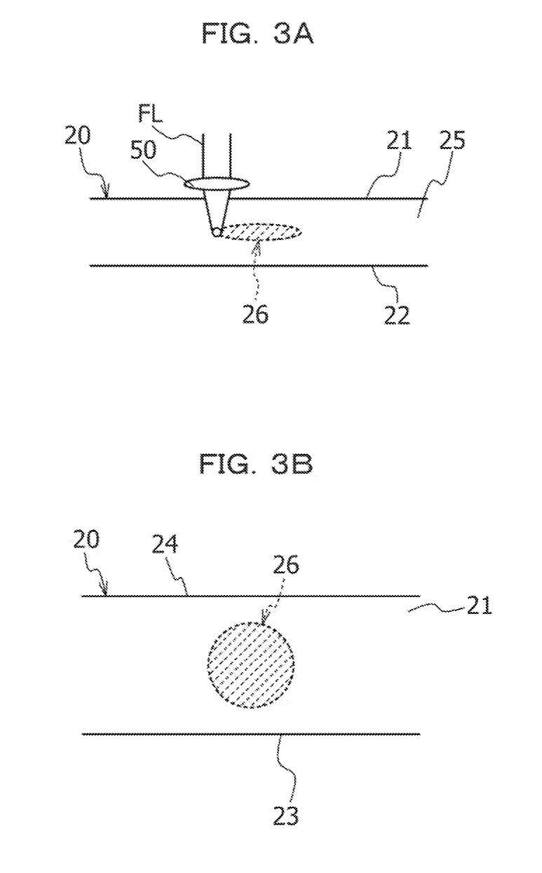

A method of forming the refractive-index-changing portion 26 in the optical transmission board 20 will now be described. FIGS. 3A and 3B illustrate a method of forming the refractive-index-changing portion 26. FIG. 3A illustrates the optical transmission board 20 seen from a side. FIG. 3B illustrates the optical transmission board 20 seen from above the top surface 21.

As illustrated in FIG. 3A, a femtosecond laser beam FL is emitted toward a condensing lens 50 such that the femtosecond laser beam FL is focused on a position inside the base substrate 25. A three-dimensional region of the base substrate 25 to which the femtosecond laser beam FL has been applied is amorphized. The amorphized region has a larger refractive index than the crystalline region.

As illustrated in FIGS. 3A and 3B, the femtosecond laser beam FL is applied to the optical transmission board 20 such that the region to which the femtosecond laser beam FL is applied has a biconvex-lens-like shape. For example, the optical transmission board 20 is placed on a stage movable in the X, Y, and Z directions, and the stage is moved such that the region to which the femtosecond laser beam FL is applied has a biconvex-lens-like shape. Thus, the region of the base substrate 25 to which the femtosecond laser beam FL has been applied is amorphized, whereby the refractive-index-changing portion 26 having a biconvex-lens-like shape is obtained. The amorphous refractive-index-changing portion 26 has a larger refractive index than the rest of the base substrate 25, which is crystalline. Other dimensional details of the refractive-index-changing portion 26 including the thickness and the diameter are adjusted appropriately in accordance with, for example, the distance between the position from which the laser beam L is emitted and the reflector 13a. The refractive index of silicon is about 3.8.

Since the refractive-index-changing portion 26 is formed by partially altering the properties of the base substrate 25 as described above, no separate members having different refractive indices from the base substrate 25 are necessary. Hence, the laser beam L that has been transmitted through the optical transmission board 20 may be converged without using any separate members having different refractive indices from the base substrate 25. If any separate member, such as a lens, is provided to the optical transmission board 20 so as to converge the laser beam L that has been transmitted through the optical transmission board 20, the separate member may come off the optical transmission board 20. Moreover, if such a separate member is attached to the optical transmission board 20, the separate member may be displaced after being attached, leading to a possibility of failing in efficiently converging the laser beam L. The first embodiment solves such a problem because a portion having a changed refractive index is formed in the base substrate 25 without the use of any separate members.

The refractive-index-changing portion 26 is formed in the base substrate 25 between the top surface 21 and the bottom surface 22 of the optical transmission board 20. Therefore, the optical transmission board 20 is maintained to be flat. For example, if any separate member having a different refractive index from the base substrate 25 is attached to the optical transmission board 20 in such a manner as to project from the top surface 21 or the bottom surface 22 of the optical transmission board 20, the separate member may interfere with the optical semiconductor device 40 or the printed circuit board 10. Consequently, the mounting height of a set of the printed circuit board 10, the optical transmission board 20, and the optical semiconductor device 40 may be large. The first embodiment solves such a problem because the optical transmission board 20 is maintained to be flat.

Moreover, since no separate members are necessary, the manufacturing cost and the number of manufacturing steps are reduced.

A method of manufacturing the optical transmission board 20 will now be described briefly.

A through hole is provided in a silicon substrate by etching. The through hole is to provide a conduction path through which the CPU 31 and the printed circuit board 10 are connected to each other. Subsequently, the silicon substrate is thermally oxidized, whereby an insulating silicon-oxide film is formed over the outer surfaces of the silicon substrate. Furthermore, the through hole is filled with a conductive material, for example, copper.

Subsequently, a wiring pattern for connecting the CPU 31 of the electronic component 30 and the printed circuit board 10 and a wiring pattern for connecting the driver 32 and the optical semiconductor device 40 are formed on the silicon substrate. The wiring patterns are formed photolithographically, avoiding the region through which the laser beam L is to travel. The wiring pattern for connecting the CPU 31 and the printed circuit board 10 is formed in such a manner as to be connected to the conductive material provided in the through hole of the silicon substrate.

A SiO₂ layer is formed on the silicon substrate having the wiring patterns, and the surface of the resulting body is ground so as to be flat. Subsequently, a hole reaching the wiring pattern for connecting the CPU 31 and the printed circuit board 10 and holes reaching the wiring pattern for connecting the driver 32 and the optical semiconductor device 40 are provided in the SiO₂ layer. The hole reaching the wiring pattern for connecting the CPU 31 and the printed circuit board 10 is to provide a conduction path through which the wiring pattern and the CPU 31 are connected to each other. The holes reaching the wiring pattern for connecting the driver 32 and the optical semiconductor device 40 are to provide conduction paths through which the wiring pattern and the driver 32 are connected to each other. The holes are provided by etching. The holes are filled with a conductive material. The holes may be filled with a conductive material by depositing a conductive metal over the entirety of the SiO₂ layer and removing the unnecessary or undesired part of the deposited metal.

Thus, the conduction path for connecting the CPU 31 and the printed circuit board 10 extends from the top surface 21 to the bottom surface 22 of the optical transmission board 20, and the conduction paths for connecting the driver 32 and the optical semiconductor device 40 extend near the top surface 21 of the optical transmission board 20.

Before the electronic component 30 and the optical semiconductor device 40 are mounted on the optical transmission board 20 manufactured as described above, the refractive-index-changing portion 26 is formed in the optical transmission board 20 by the method described above. The refractive-index-changing portion 26 is formed at a position avoiding the wiring patterns.

Subsequently, the electronic component 30 and the optical semiconductor device 40 are mounted on the optical transmission board 20. Thus, the optical transmission device according to the first embodiment is obtained.

The wiring pattern for connecting the driver 32 and the optical semiconductor device 40 may alternatively be formed on the printed circuit board 10, not on the optical transmission board 20. In that case, a plurality of through holes are provided in a silicon substrate, and a silicon-oxide film is formed over the outer surfaces of the silicon substrate. Subsequently, the through holes are filled with a conductive material, whereby electrodes extending through the silicon substrate are obtained. The electrodes provide the connection between the driver 32 and the printed circuit board 10 and the connection between the printed circuit board 10 and the optical semiconductor device 40.

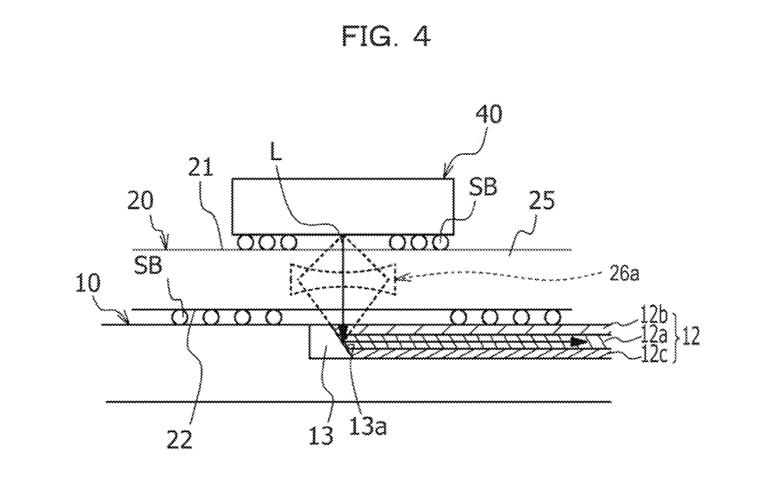

FIG. 4 illustrates an optical transmission device according to a second embodiment.

An optical transmission board 20a has thereinside a refractive-index-changing portion 26a. The refractive-index-changing portion 26a is a hollow. The refractive-index-changing portion 26a has a smaller refractive index than the base substrate 25. Specifically, the refractive index of the refractive-index-changing portion 26a is about 1. The refractive-index-changing portion 26a has a biconcave-lens-like shape in side view of the optical transmission board 20a. The laser beam L emitted from the optical semiconductor device 40 enters the base substrate 25, travels through the refractive-index-changing portion 26a, and reenters the base substrate 25. Since the laser beam L travels through the refractive-index-changing portion 26a, the laser beam L converges toward the reflector 13a.

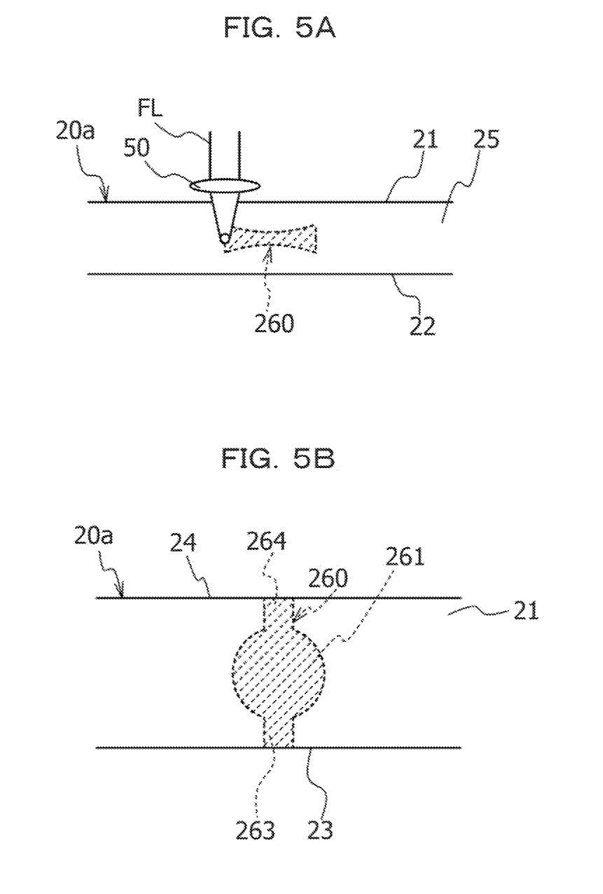

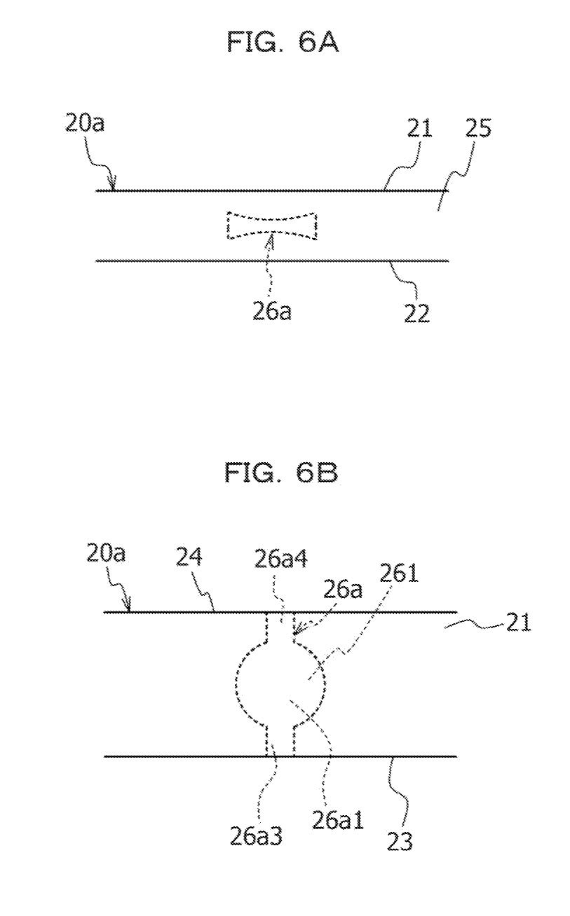

A method of forming the refractive-index-changing portion 26a in the optical transmission board 20a according to the second embodiment will now be described. FIGS. 5A, 5B, 6A, and 6B illustrate a method of forming the refractive-index-changing portion 26a in the optical transmission board 20a according to the second embodiment. FIGS. 5B and 6B illustrate the optical transmission board 20a seen from the top surface 21. As illustrated in FIG. 5B, a femtosecond laser beam FL is applied to a region inside the base substrate 25. Specifically, a beam-applied region 260 includes a biconcave-lens-like beam-applied region 261, a beam-applied region 263 extending from the beam-applied region 261 to a side face 23, and a beam-applied region 264 extending from the beam-applied region 261 to another side face 24. The femtosecond laser beam FL is applied to the beam-applied region 260 for amorphization. Thus, the properties of the beam-applied region 260 are altered.

Subsequently, wet etching is performed so as to remove the beam-applied region 260. Examples of the etching liquid used in wet etching include hydrofluoric acid, sulfuric acid, nitric acid, hydrochloric acid, phosphoric acid, and a mixed solution of hydrogen fluoride, nitric acid, and acetic acid. The beam-applied region 260 is removed by wet etching. Thus, the refractive-index-changing portion 26a, which is a hollow, is provided in the optical transmission board 20a. The refractive-index-changing portion 26a includes a biconcave-lens-like central portion 26a1, an extending portion 26a3 extending from the central portion 26a1 to the side face 23, and another extending portion 26a4 extending from the central portion 26a1 to the side face 24.

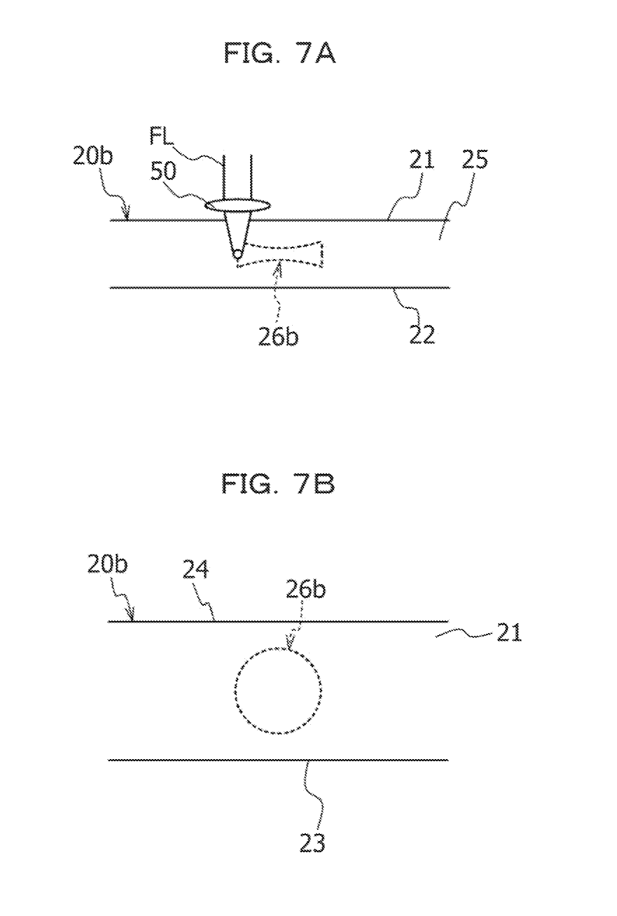

A variation of the method of forming the refractive-index-changing portion in the optical transmission board according to the second embodiment will now be described. FIGS. 7A and 7B illustrate a variation of the method of forming the refractive-index-changing portion in the optical transmission board according to the second embodiment. As illustrated in FIG. 7A, a femtosecond laser beam FL is applied to a region inside the base substrate 25, and the region of the base substrate 25 is evaporated by ablation, whereby a hollow refractive-index-changing portion 26b is obtained. That is, the hollow refractive-index-changing portion 26b is formed by applying a femtosecond laser beam FL to a part of the base substrate 25 and thus altering the properties of that part of the base substrate 25. As illustrated in FIG. 7B, the refractive-index-changing portion 26b has a circular shape when seen from above the top surface 21. In this variation, the refractive-index-changing portion 26b does not include the extending portions 26a3 and 26a4 extending to the respective side faces 23 and 24 included in the refractive-index-changing portion 26a illustrated in FIGS. 6A and 6B.

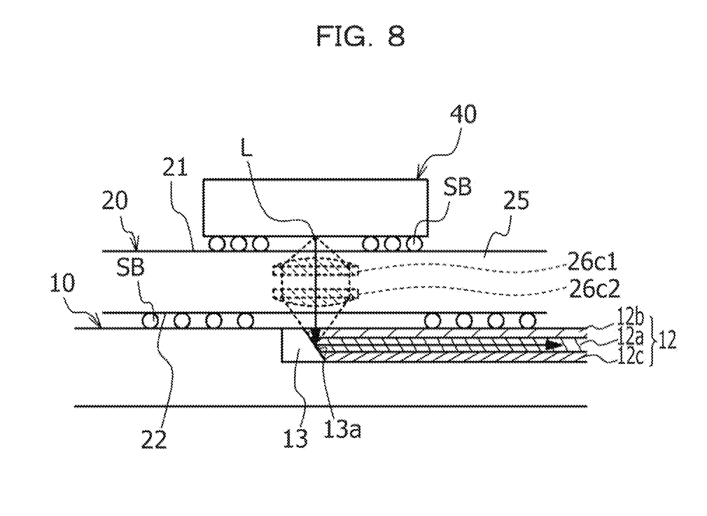

An optical transmission device according to a third embodiment will now be described. FIG. 8 illustrates an optical transmission device according to the third embodiment. As illustrated in FIG. 8, an optical transmission board 20c has thereinside refractive-index-changing portions 26c1 and 26c2 provided side by side in the thickness direction of the optical transmission board 20c. The refractive-index-changing portions 26c1 and 26c2 have larger refractive indices than the base substrate 25, and are amorphous. The refractive-index-changing portions 26c1 and 26c2 each have a plano-convex-lens-like shape. The refractive-index-changing portion 26c1 near the optical semiconductor device 40 has the convex surface thereof facing the optical semiconductor device 40. The refractive-index-changing portion 26c2 near the printed circuit board 10 has the convex surface thereof facing the printed circuit board 10. The planar surface of the refractive-index-changing portion 26c1 and the planar surface of the refractive-index-changing portion 26c2 face each other. As is the refractive-index-changing portion 26 according to the first embodiment, the refractive-index-changing portions 26c1 and 26c2 are formed by applying a femtosecond laser beam FL.

The laser beam L emitted from the optical semiconductor device 40 diverges radially before entering the refractive-index-changing portion 26c1. The laser beam L that has entered the convex surface of the refractive-index-changing portion 26c1 travels through the refractive-index-changing portion 26c1 and is emitted from the planar surface of the refractive-index-changing portion 26c1 in a substantially collimated form. The laser beam L emitted from the refractive-index-changing portion 26c1 travels through the base substrate 25 and enters the planar surface of the refractive-index-changing portion 26c2. The laser beam L further travels through the refractive-index-changing portion 26c2 and is emitted from the refractive-index-changing portion 26c2 in such a manner as to gradually converge. The laser beam L emitted from the refractive-index-changing portion 26c2 converges on the reflector 13a and is reflected.

With the plano-convex-lens-like refractive-index-changing portions 26c1 and 26c2 formed as described above, the laser beam L traveling from the refractive-index-changing portion 26c1 to the refractive-index-changing portion 26c2 is collimated. Thus, the laser beam L traveling from the refractive-index-changing portion 26c1 to the refractive-index-changing portion 26c2 is substantially prevented from diverging radially.

For example, in a case where an optical semiconductor device capable of emitting a plurality of parallel laser beams L from a plurality of emission points is employed, if a plurality of refractive-index-changing portions are provided side by side in the planar direction of the optical transmission board, the intervals of the laser beams L to be emitted may not be made very small. This is because each laser beam L travels through the optical transmission board while diverging radially, and the sizes of the refractive-index-changing portions are to be determined considering the extent of the radial divergence of the laser beam L. Hence, in such a case, the size of the optical transmission board increases in the planar direction. In contrast, the optical transmission board 20c according to the third embodiment has the plano-convex-lens-like refractive-index-changing portions 26c1 and 26c2 provided thereinside side by side in the thickness direction of the optical transmission board 20c. Therefore, the radial divergence of the laser beam L is suppressed. Thus, even in the case where an optical semiconductor device capable of emitting a plurality of laser beams L from a plurality of emission points is employed, the size increase of the optical transmission board in the planar direction is suppressed.

An optical transmission device according to a fourth embodiment will now be described.

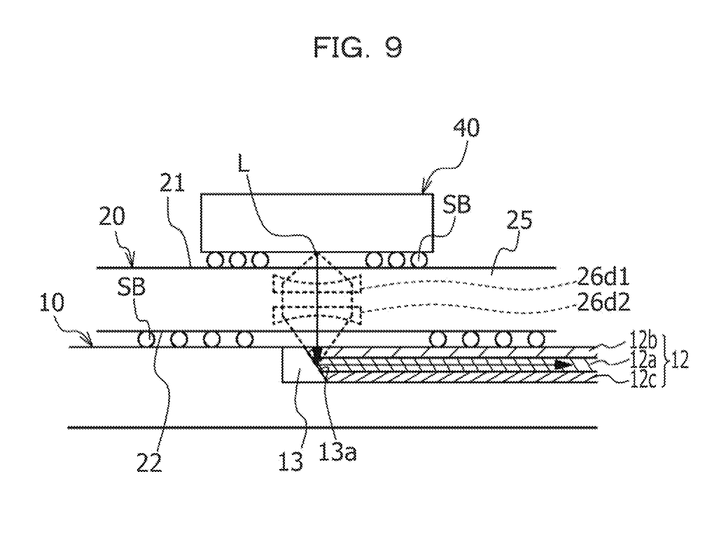

FIG. 9 illustrates an optical transmission device according to the fourth embodiment. As illustrated in FIG. 9, an optical transmission board 20d has thereinside refractive-index-changing portions 26d1 and 26d2 provided side by side in the thickness direction of the optical transmission board 20d. The refractive-index-changing portions 26d1 and 26d2 are hollows and have smaller refractive indices than the base substrate 25. The refractive-index-changing portions 26d1 and 26d2 are each a plano-concave-lens-like shape. The refractive-index-changing portion 26d1 near the optical semiconductor device 40 has the concave surface thereof facing the optical semiconductor device 40. The refractive-index-changing portion 26d2 near the printed circuit board 10 has the concave surface thereof facing the printed circuit board 10. The planar surface of the refractive-index-changing portion 26d1 and the planar surface of the refractive-index-changing portion 26d2 face each other.

The refractive-index-changing portions 26d1 and 26d2 may be provided by amorphizing relevant regions by applying a femtosecond laser beam FL thereto, and then removing the amorphized regions by wet etching, or may be provided by ablation.

With the plano-concave-lens-like refractive-index-changing portions 26d1 and 26d2 provided as described above, the laser beam L traveling from the refractive-index-changing portion 26d1 to the refractive-index-changing portion 26d2 is collimated. Thus, the laser beam L traveling from the refractive-index-changing portion 26d1 to the refractive-index-changing portion 26d2 is substantially prevented from diverging radially. Hence, even in the case where an optical semiconductor device capable of emitting a plurality of laser beams L from a plurality of emission points is employed, the size increase of the optical transmission board in the planar direction is suppressed.

While preferred embodiments of the present invention have been described in detail, the present invention is not limited thereto, and various changes and modifications may be made thereto within the scope of the present invention disclosed in the appended claims.

While the optical transmission boards 20 to 20d are made of silicon (Si), the optical transmission boards 20 to 20d may be made of a material including at least one of the following: gallium arsenide (GaAs), indium phosphide (InP), lithium niobate (LiNbO₃), and silicon dioxide (SiO₂).

Various procedures included in the method of manufacturing the optical transmission board other than the method of forming the refractive-index-changing portion 26 in the optical transmission board are not limited to those disclosed in this specification.

All examples and conditional language recited herein are intended for pedagogical purposes to aid the reader in understanding the invention and the concepts contributed by the inventor to furthering the art, and are to be construed as being without limitation to such specifically recited examples and conditions. Although the embodiment has been described in detail, it should be understood that various changes, substitutions, and alterations could be made hereto without departing from the spirit and scope of the invention.

What is claimed is:

1. An optical device comprising:
a base having light transmissibility; and
an amorphized part provided in a lens-like shape in the base, the lens-like shape part having a different refractive index from the rest of the base.

2. The optical device according to claim 1, wherein:
the base is crystalline, and
the lens-like shape part has a larger refractive index than the rest of the base.

3. The optical device according to claim 1, wherein the lens-like shape part is a wet-etched part, has a smaller refractive index than the base, and is hollow.

4. The optical device according to claim 1, wherein the base is a material that includes at least one of Si, GaAs, InP, LiNbO₃, and SiO₂.

5. An optical transmitter-receiver comprising:
an optical transmission board including,
a base having light transmissibility and
an amorphized part provided in a lens-like shape in the base, the lens-like shape part having a different refractive index from the base; and
an optical semiconductor device mounted on the optical transmission board.

6. The optical transmitter-receiver according to claim 5, wherein:
The base is crystalline and is a material that includes at least one of Si, GaAs, InP, LiNbO₃, and SiO₂; and
The lens-like shape part has a larger refractive index than the rest of the base.

7. The optical transmitter-receiver according to claim 5, wherein:
The base is crystalline and is a material that includes at least one of Si, GaAs, InP, LiNbO₃, and SiO₂; and
The lens-like shape part is a wet-etched part, has a smaller refractive index than the base, and is hollow.

8. A method of manufacturing an optical device, comprising:
applying a femtosecond laser beam to a three-dimensional region inside a transmissibility base such that the region has a lens-like shape; and
continuing to apply the femtosecond laser beam until the region is amorphized.

9. The method of manufacturing an optical transmission board according to claim 8, further comprising:
continuing to apply the femtosecond laser beam until the region extends to a side face of the base; and
performing wet etching on the region.

10. The method of manufacturing an optical transmission board according to claim 8, further comprising:
continuing to apply the femtosecond laser beam until the region is evaporated.
